(19) United States
(12) Patent Application Publication
(10) Pub. No.: US 2001/0043075 A1
(43) Pub. Date: Nov. 22, 2001

(54) Apparatus for inspecting IC wafer

(76) Inventor: Etusji Suzuki, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 09/814,963

(22) Filed: Mar. 23, 2001

(30) Foreign Application Priority Data
May 16, 2000 (JP) 2000-143867

(51) Int. Cl. G01R 31/02

(52) U.S. Cl. 324/763

(57) ABSTRACT

An apparatus for inspecting an IC wafer is disclosed in which an IC chips array on the IC wafer is divided into plural groups and inspection is carried out for each group. This apparatus comprises an inspection circuit board 4 for sending and receiving a signal to and from the IC chips 7 array, a common wiring board 3 having a signal main line 8 common to the respective IC chips 7 array of each group and for connecting the tester main body 1 to the inspection circuit board 4, and a resistor array board 11 having a plurality of protective resistors R. The inspection circuit board 4, the common wiring board 3 and the resistor array board 11 are arranged between the inspection circuit board 4 and the common wiring board 3 through the resistor array board 11 such that surfaces of the boards 4, 3, 11 are in opposing relation to each other. One end of each protective resistor R is connected to the inspection circuit board 4 at one surface of the resistor array board 11 and the other end is connected to the common wiring board 3 at the other surface of the resistor array board 11.

### BACKGROUND OF THE INVENTION

1. Field of the Invention

This invention relates to an apparatus for inspecting an IC wafer, in which an IC chips array on an IC wafer is divided into plural groups and an inspection is carried out for each group. This is a related application to Japanese Patent No. 3046725.

2. Related Art

Attempts are made to carry out an inspection method in which several hundreds of IC chips are arranged on an IC wafer in a vertical and a horizontal row, a probe unit is contacted with the array of those IC chips and the probe unit and a tester main body are connected to each other through a signal line, so that a burn-in inspection, etc. of the IC chips array can be conducted on a wafer level.

However, this method has the following problems. Only one IC chip on only one IC wafer has several tens to several hundreds of external contacts on an IC wafer. In order to make an access to such several hundreds of IC chips on only one IC wafer, a number of signal lines obtained by multiplying a number of external contacts of only one IC chip to a number of arrays of IC chips is required. To obtain such a large number of signal lines, such an extremely high degree of technique is required as to form a multilayer wiring board which has a high density of wiring patterns which are drawn at extremely small pitches. In addition, a high manufacturing cost is inevitably required. Because of those reasons, the above method is prevented from being widely employed in industries.

Moreover, the conventional method has the following additional problem. Due to difference of thermal expansion between the IC wafer and the member for retaining contactor of the probe unit, the external contact on the IC wafer and the contactor are displaced from each other, thus resulting in insufficient electrical contact.

### SUMMARY OF THE INVENTION

It is, therefore, an object of the present invention to provide an apparatus for inspecting an IC wafer capable of efficiently solving the above-mentioned problems.

This apparatus is of the type in which an IC chips array on the IC wafer is divided into plural groups and inspection is carried out for each group. It comprises an inspection circuit board for sending and receiving a signal to and from the IC chips array on the IC wafer, a common wiring board having a signal main line common to the respective IC chips array of each group and for connecting the tester main body to the inspection circuit board, and a resistor array board having a plurality of protective resistors.

The inspection circuit board, the common wiring board and the resistor array board are arranged between the inspection circuit board and the common wiring board through the resistor array board such that surfaces of the boards are in opposing relation to each other. One end of each protective resistor is connected, either directly or indirectly, to the inspection circuit board at one surface of the resistor array board and the other end is connected, either directly or indirectly, to the common wiring board at the other surface of the resistor array board.

According to this inspection apparatus, by commonly using the signal main line for each group, the number of the common signal lines can extensively be reduced to a number which is obtained by dividing a number of total branch lines by a number of groups.

Since the IC chips array on the IC wafer is divided into plural groups and an inspection circuit board is formed for each group, the difference of thermal expansion between the IC wafer and the inspection circuit board is reduced as much as possible and a sufficient electrical contact between the external contact on the IC wafer and the contactor is obtained.

Moreover, the purpose of insertion of the protective resistor in each group is easily achieved by a provision of only one resistor array board. Owing to insertion of the protective resistor, even if a short-circuit breakage should occur to a certain IC chip in a group, short of supply of electric power, which would otherwise occur to those IC chips in other groups, could effectively be prevented by the protective resistor. Thus, the inspection for each group can properly be carried out.

Moreover, the assembly of the inspection circuit board, the common wiring board and the resistor array board can be constituted easily and efficiently, and the large number of protective resistors array can be divided into groups and orderly arranged. In addition, maintenance and replacement are easy in the case where the protective resistor is broken.

Moreover, the inspection circuit board, the resistor array board and the common wiring board are arranged such that surfaces of those boards are in opposing relation to each other. At each surface of the resistor array board, the opposite ends of each protective resistor are contacted with the inspection circuit board and the common wiring board, respectively. By doing so, the purpose of insertion of the protective resistor and the thinner design of the entire apparatus can be achieved simultaneously.

In addition to the above-mentioned constitution, by interposing the resistor array board between the inspection circuit board and the common wiring board thereby to form an assembly of the three component parts, the protective resistor can be press-sandwiched between the two boards so that an electrical contact of the protective resistor is achieved under an appropriate pressure.

Preferably, the resistor array board has a grounding contact so that a grounding line is easily formed between the common wiring board and the inspection circuit board.

Preferably, the resistor array board has a power source contact so that a power source line is easily formed between the common wiring board and the inspection circuit board.

### BRIEF DESCRIPTION OF THE DRAWINGS

FIG. 1 shows a schematic circuit diagram of an apparatus for inspecting an IC wafer by means of two groups of IC chips array;

FIG. 2 is a sectional view showing one example of a construction of an assembly formed by superimposing, one upon another, a common wiring board, a resistor array board and an inspection circuit board;

FIG. 3 is a sectional view showing another example of a construction of an assembly formed by superimposing, one upon another, a common wiring board, a resistor array board and an inspection circuit board;

FIG. 4 is a plan view showing a porous plate forming the resistor array board in which a protective resistor is omitted;

FIG. 5 is a plan view showing another example of the porous plate in which a protective board is omitted;

FIG. 6 is a sectional view of the protective resistor board; and

FIG. 7 is an enlarged sectional view of the porous plate forming the resistor array board.

### DETAILED DESCRIPTION OF THE EMBODIMENT

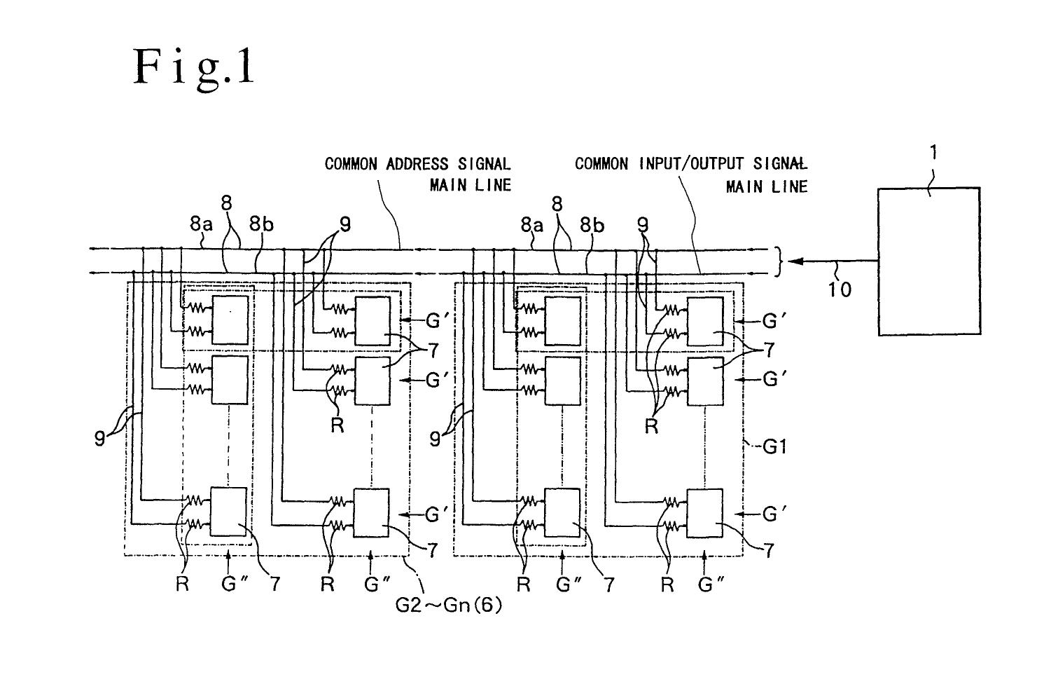

One embodiment of the present invention will now be described with reference to FIGS. 1 to 7 of the accompanying drawing.

In FIGS. 1 to 7, reference numeral 1 denotes a tester main body and 2, a probe unit (inspection unit), respectively. The probe unit 2 includes a common wiring board 3 and an inspection circuit board 4. The inspection circuit board 4 is comprised of a multilayer wiring circuit board. One surface of the inspection circuit board 4 is connected to an end part of a branch line 9 which is branched from a common signal main line 8 formed on the common wiring circuit board 3. The other surface of the inspection circuit board 4 is provided with a plurality of electrode pads 30 which are connected to external contacts of IC chips 7 on an IC wafer 6 through a contactor 5.

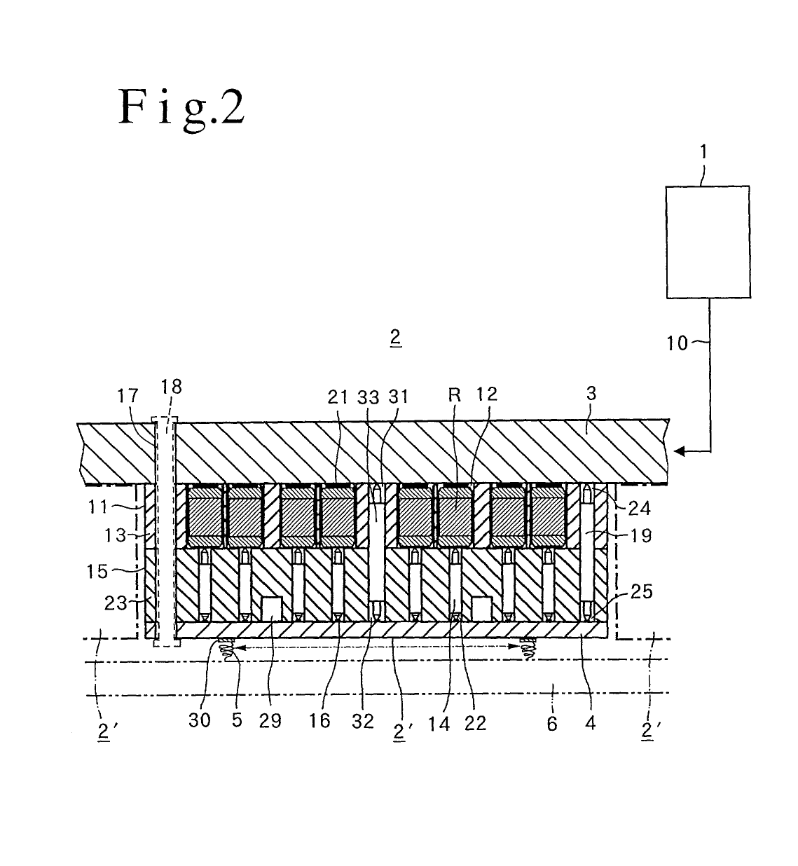

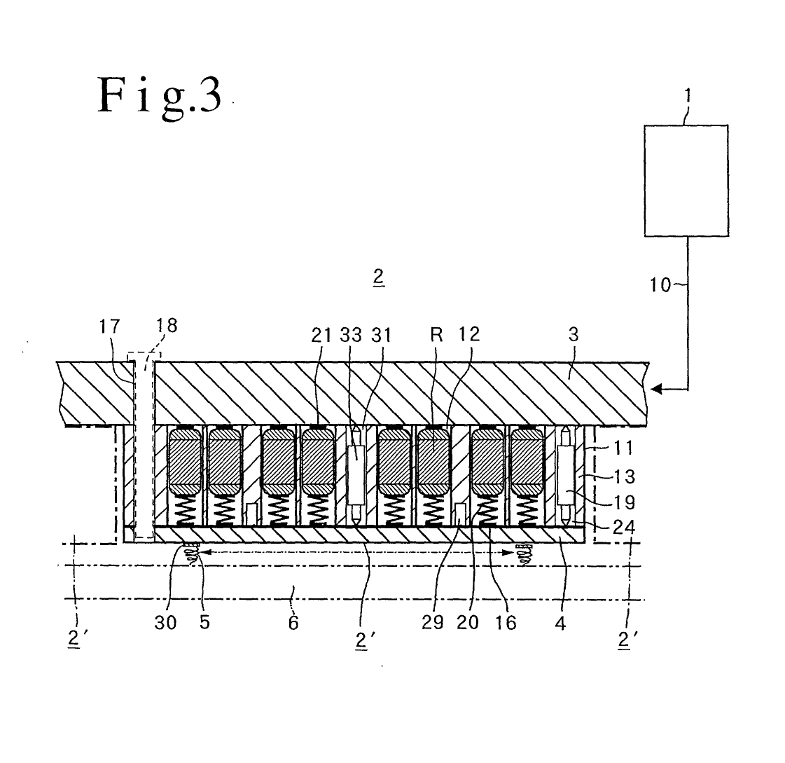

As a specific example of the contactor 5, FIGS. 2 and 3 show a coiled spring. One winding end of the coiled spring is fixedly connected to the electrode pads 3 and the other winding end is forcibly elastically connected to external contacts of the IC chips 7. The connector 5 composed of this coiled spring is flexed in accordance with the difference of thermal expansion between the IC wafer 6 and the boards 3, 4 and absorbs the difference of thermal expansion.

The multilayer wiring circuit board forming the inspection circuit board 4 has a wiring pattern forming the branch lines 9.

On the other hand, the common wiring board 3 is a multilayer wiring board which forms the signal main line 8 common to each IC chips 7 array divided into groups. This common wiring board 3 is formed by sticking a backup plate such as a ceramic plate or a glass plate which is scarcely thermally expanded to a base plate such as, for example, the multilayer wiring board which is scarcely thermally expanded, thereby constraining the inspection circuit board 4 to restrain its thermal expansion.

The apparatus for inspecting an IC wafer according to the present invention is an inspection apparatus in which the IC chips 7 array on the IC wafer 6 is divided into plural groups G1 to Gn and inspection is carried out for each group. In the case where, for example, 200 IC chips 7 are formed the IC wafer 6, those IC chips 7 are divided into, for example, 10 groups and 20 IC chips in a group G are inspected for each group.

The expression, “common signal main line 8” used herein refers to a common address signal main line, a common input/output signal main line or the like in the case where the IC chips 7 are memory IC.

Although there exist other lines such as a common power main line, a vertical/horizontal row selection signal main line for selecting the IC chips 7 array in a vertical and a horizontal row, a grounding main line, and the like, they are omitted for the sake of simplicity of explanation. In FIG. 1, a common address signal main line 8a and a common input/output signal main line 8b are shown as the common signal main line 8.

An end part of the common wiring board 3 and the tester main body 1 are connected to the common signal main line 8, etc. on the common wiring board 3 through a cable 10.

As described above, in the apparatus for inspecting an IC wafer, the IC chips 7 array on the IC wafer 6 is divided into plural groups G1 to Gn and inspection is carried out for each group. On the other hand, as shown in FIG. 1, as well as in elsewhere, the common signal main line 8 is formed to connect the probe unit 2 capable of contacting the IC chips 7 group for sending and receiving signal to the tester unit 1. A protective resistor R is inserted in a branch line 9 which is branched from the common signal main line 8 and led into each IC chip 7 in the group G.

As shown in FIGS. 2 and 3, the inspection circuit board 4 for sending and receiving signal to and from the IC chips 7 array on the IC wafer 6 and the common wiring board 3 having the common signal main line 8 common to the respective IC chips 7 array of each group and for connecting the tester main body 1 to the inspection circuit board 4 are formed.

On the other hand, a resistor array board 11 having a plurality of protective resistors R is formed. This resistor array board 11 is interposed between the inspection circuit board 4 and the common wiring board 3 such that the surfaces (plate faces) of the boards 4, 3, 11 are in opposing relation to each other.

At one surface of the resistor array board 11 interposed between the inspection circuit board 4 and the common wiring board 3, one end of each protective resistor R is contacted, either directly or indirectly, with the inspection circuit board 4, and at the other surface of the resistor array board 11, the other end of each protective resistor R is contacted, either directly or indirectly, with the common wiring board 3.

Owing to the above construction, each protective resistor R is inserted in each branch line 9, which is branched from the common signal main line 8 on the common wiring board 3 and led to each IC chip 7 in each group, through the resistor array board 11.

An example of a specific construction for allowing insertion of the protective resistor R will now be described with reference to FIG. 2. A double face multi-point connection plate 15 having a plurality of contactors 14 is interposed between the inspection circuit board 4 and the resistor array board 11. Then, the common wiring board 3, the resistor array board 11, the double face multi-point connection plate 15 and the inspection circuit board 4 are superimposed such that their surfaces (plate faces) are in opposing relation to each other, thereby forming a superimposed assembly 2′ (probe unit 2).

A plurality of such superimposed assemblies 2′ are juxtaposed on an entire surface of the common wiring board 3. The superimposed assemblies 2′ are subjected to connection with the IC chips 7 array on the semiconductor wafer 6 so that the tester main body 1 and the IC chips 7 array are connected to each other.

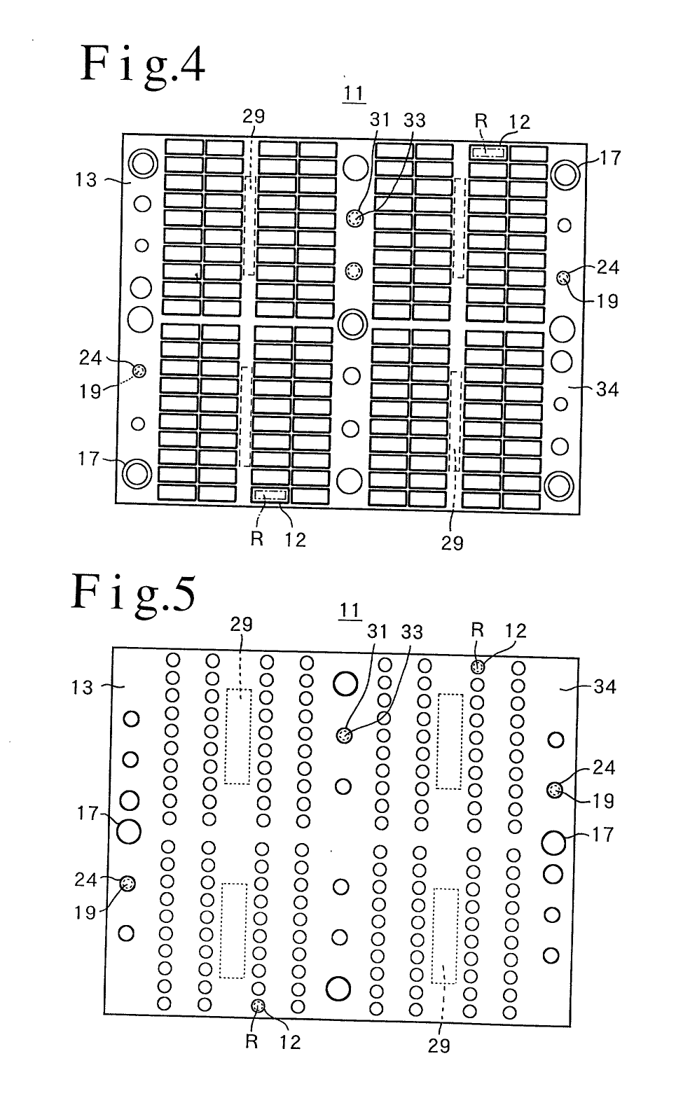

The resistor array board 11 constituting the superimposed assembly 2′, has, as shown in FIGS. 4 and 5, a porous plate 13 having a plurality of through-holes 12 which are arranged in juxtaposed relation to each other and open at opposite surfaces. The protective resistor R is loosely inserted in each through-hole 12 of the porous plate 13.

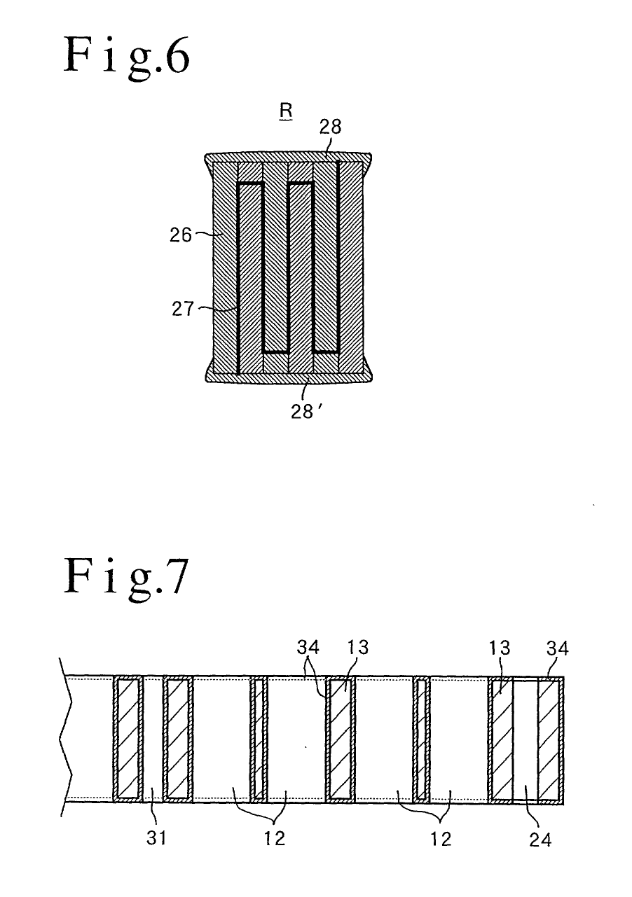

The protective resistor R, as shown in FIG. 6, is formed by disposing a wiring 27 between every adjacent layer of a multilayer insulative block 26 which is composed of a laminated body of insulative pieces made of ceramics or the like. One end of the wiring 27 is contacted with an electrode 28 which is intimately contacted with an upper end of the multilayer insulative block 26 and the other end is contacted with an electrode 28′ which is intimately contacted with a lower end of the block 26. The electrodes 28, 28′ are formed of a low melting point metal such as Sn or the like. The entire protective resistor R exhibits, for example, a prismatic or circular column-like configuration.

Each protective resistor R is withdrawably inserted into each through-hole 12 of the porous plate 13 such that only a broken protective resistor R can be replaced. Each through-hole 12 has a prismatic or circular column-like configuration in match with that of the protective resistor R which is to be inserted into the through-hole 12.

The double face multi-point connection plate 15, which is superimposed on the resistor array board 11 to constitute the superimposed assembly 2′, has a plurality of contactors 14 which have compression elasticity in the width direction of the connection plate 15. One end of each contactor 14 is press contacted with one end of the protective resistor R and the other end is press contacted with an electrode pad 16 which is arranged on one surface (superimposing surface) of the inspection circuit board 4. In order to more surely realize the press contact of the opposite ends of each contactor 14, each contact part may be soldered.

For example, the double face multi-point connection plate 15 forms a porous plate 23 having a plurality of through-holes 22 which are open at opposing two surfaces, and a pin-type contactor 14 is withdrawably loosely inserted in each through-hole 22 in the axial direction of the through-hole 22. The porous plate 13 has a recess 29 formed in its surface opposing the inspection circuit board 4. An electronic part such as a power condenser chip provided on the inspection circuit board 4 is received in the recess 29.

By forming the superimposed assembly 2′ composed of the common wiring board 3, the resistor array board 11, the double face multi-point connection plate 15 and the inspection circuit board 4, the contactor 14 is compressed to accumulate the elastic force. By its repulsive force, the press contact relation is ensured.

That is to say, the resistor array board 11 and the multi-point connection plate 15 are interposed between the common wiring board 3 and the inspection circuit board 4 in their superimposed relation, such that the surfaces of the boards 3, 11, 15, 4 are in mutually opposing relation. Owing to this arrangement, one end of each protective resistor R is press contacted with the electrode pad 16 of the inspection circuit board 4 through the contactor 14 at one surface of the resistor array board 11, and the other end of the protective resistor R is press contacted, either directly or indirectly, with the superimposing surface of the common wiring board 3 at the other surface of the resistor array board 11.

The electrode pad 21 is adapted to make a branch wiring of the branch line 9 provided on the common signal main line 8 side. The branch line 9 and the protective resistor R are branch connected to the common signal main line 8 through the electrode pad 21.

That is to say, at each surface of the resistor array board 11, the branch line 9 from the common signal main line 8 and the wiring pattern of the inspection circuit board 4 are electrically connected to each other through each protective resistor R and each contactor 14, and each protective resistor R is properly inserted in each branch line 9.

The common wiring board 3, the resistor array board 11, the double face multi-point connection plate 15 and the inspection circuit board 4 are formed with a screwing hole 17 communicating with all of those boards. A screw 18 is inserted into the screwing hole 17, thereby integrally firmly tightening those boards which are superimposed in the above-mentioned order. The resistor array board 11 and the double face multi-point connection plate 15 are press sandwiched between the inspection circuit board 4 and the common wiring board 3.

It is also accepted that the common wiring board 3, the resistor array board 11 and the double face multi-point connection plate 15 are held in superimposed relation and tightened by the screw 18, and then the inspection circuit board 4 is adhered to the superimposed body.

Owing to the above arrangement, a press superimposed state of the boards 3, 11, 15, 4 is held, and a press contacting state among the opposite ends of the protective resistor R, the electrode pad 21 arranged on the surface of the common wiring board 3 and the electrode pad 16 arranged on the surface of the inspection circuit board 4 is ensured, thereby enhancing the reliability of electrical contact.

The resistor array board 11 has a pin-type grounding contact 19 in a through-hole 24 of the board 11. The through-hole 24 of the resistor array board 11 and a through-hole 25 of the double face multi-point connection plate 15 are communicated with each other, the grounding contact 19 is loosely inserted into the through-holes 24, 25, and a grounding line is formed between the common wiring board 3 and the inspection circuit board 4 through the grounding contact 19. The grounding contact 19 is a contactor having compression elasticity in the thickness direction of the resistor array board 11 and the double face multi-point connection plate 15.

As shown in FIG. 7, the porous plate 13 forming the resistor array board 11 is formed of a metal plate, and the opposing two surfaces of the metal-made porous plate 13 and the inner peripheral surface of each through-hole 12 for loosely inserting therein each protective resistor R are coated 34 with an insulative material. On the other hand, the inner peripheral surface of the through-hole 24 for loosely inserting therein the grounding contact 19 is not applied with the insulative coating 34. Instead, the metal is allowed to expose outside at the inner peripheral surface of the through hole 24 so that the grounding contact 19 can contact the conductive metal surface, thereby enhancing the grounding effect.

The metal-made porous plate 13 is connected to the grounding line at its proper place. By doing so, signal can be sent at a high speed and thus, a high speed inspection can be realized.

The through-hole 31, whose inner peripheral surface is applied with the insulative coating 34, of the resistor array board 11 is communicated with the through-hole 32 of the double face multi-point connection plate 15, and a pin-type power contact 33 is loosely inserted into the through holes 31, 32. The power contact 33 is a contactor having a compression elasticity in the thickness direction of the boards 11, 15. The common power main line of the common wiring board 3 and the power line of the inspection circuit board 4 are connected to each other, so that electric power can be supplied to each IC chips 7 array.

Another specific example of a construction for inserting the protective resistor R will now be described with reference to FIG. 3. The inspection circuit board 4, the resistor array board 11 and the common wiring board 3 are superimposed with their surfaces placed in opposing relation, to thereby form the superimposed assembly 2′ (probe unit 2).

A plurality of such superimposed assemblies 2′ are arranged in juxtaposed relation over the entire surface of the common wiring board 3 and each superimposed assembly 2′ is subjected to connection with each IC chips 7 array on the semiconductor wafer 6, so that the tester main body 1 and the IC chips 7 array are connected to each other.

The superimposed assembly 2′, as shown in FIGS. 4 and 5, has a porous plate 13 provided with a plurality of through-holes 12 which are arranged in juxtaposed relation to each other and which are open at the opposing two surfaces thereof. Each protective resistor R is loosely inserted in each through-hole 12 of the porous plate 13.

The protective resistor R, as shown in FIG. 6, is formed by disposing between every adjacent layer of a multilayer insulative block 26 which is composed of a laminated body of insulative pieces made of ceramics or the like. One end of the wiring 27 is contacted with an electrode 28 which is intimately contacted with an upper end of the multilayer insulative block 26 and the other end is contacted with an electrode 28′ which is intimately contacted with a lower end of the block 26. The electrodes 28, 28′ are formed of a low melting point metal such as Sn or the like. The entire protective resistor R exhibits, for example, a prismatic or circular column-like configuration.

Each protective resistor R is withdrawably inserted into each through-hole 12 of the porous plate 13 such that only a broken protective resistor R can be replaced. Each through-hole 12 has a prismatic or circular column-like configuration in match with that of the protective resistor R which is to be inserted into the through-hole 12.

The porous plate 13 has a spring 20 for resiliently holding the protective resistor R in the through-hole 12. For example, it has, as illustrated, a spring 20 having a compression elasticity on its side opposing the inspection circuit board 4.

In this case, one end of the protective resistor R is press contacted with an electrode pad 21 which is arranged on the superimposing surface of the common wiring board 3, and the other end is press contacted with an electrode pad 16 arranged on one surface (superimposing surface) of the inspection circuit board 4 through the spring 20. In order to more surely realize this press contact relation, each contact part may be soldered.

By forming the superimposed assembly 2′ composed of the common wiring board 3, the resistor array board 11, and the inspection circuit board 4, the spring 20 is compressed to accumulate the elastic force. By its repulsive force, the press contact relation is ensured.

That is to say, the resistor array board 11 is interposed between the common wiring board 3 and the inspection circuit board 4 in their superimposed relation, such that the surfaces of the boards 3, 11, 4 are in mutually opposing relation. Owing to this arrangement, one end of each protective resistor R is press contacted, either directly or indirectly, with the electrode pad 16 of the inspection circuit board 4 through the spring 20 at one surface of the resistor array board 11, and the other end of the protective resistor R is press contacted, either directly or indirectly, with the electrode pad 16 of the common wiring board 3 at the other surface of the resistor array board 11.

The electrode pad 21 is adapted to make a branch wiring of the branch line 9 provided on the common signal main line 8 side. The branch line 9 and the protective resistor R are branch connected to the common signal main line 8 through the electrode pad 21.

That is to say, both surfaces of the resistor array board 11, the branch line 9 from the common signal main line 8 and the wiring pattern of the inspection circuit board 4 are electrically connected to each other through each protective resistor R and each spring 20, and each protective resistor R is properly inserted in each branch line 9.

The porous plate 13 constituting the resistor array board 11 has a recess 29 at its surface opposing the inspection circuit board 4 as indicated by dotted line in FIGS. 4 and 5. Electronic parts such as a power condenser chip and the like on the inspection circuit board 4 are received in the recess 29.

The common wiring board 3, the resistor array board 11 and the inspection circuit board 4 are formed with a screwing hole 17 communicating with all of those boards. A screw 18 is inserted into the screwing hole 17, thereby integrally firmly tightening those boards which are superimposed in the above-mentioned order. The resistor array board 11 is press sandwiched between the inspection circuit board 4 and the common wiring board 3.

It is also accepted that the common wiring board 3 and the resistor array board 11 are held in superimposed relation and tightened by the screw 18, and then the inspection circuit board 4 is adhered to the superimposed body.

Owing to the above arrangement, a press superimposed state of the boards 3, 11, 4 is held, and a press contacting state among the opposite ends of the protective resistor R, the electrode pad 21 arranged on the surface of the common wiring board 3 and the electrode pad 16 arranged on the surface of the inspection circuit board 4 is ensured, thereby enhancing the reliability of electrical contact.

The resistor array board 11 has a pin-type grounding contact 19 in a through-hole 24 of the board 11. The grounding contact 19 is loosely inserted into the through-hole 24, and a grounding line is formed between the common wiring board 3 and the inspection circuit board 4 through the grounding contact 19. The grounding contact 19 is a contactor having compression elasticity in the thickness direction of the resistor array board 11.

As shown in FIG. 7, the porous plate 13 forming the resistor array board 11 is formed of a metal plate, and the opposing two surfaces of the metal-made porous plate 13 and the inner peripheral surface of each through-hole 12 for loosely inserting therein each protective resistor R are coated 34 with an insulative material. On the other hand, the inner peripheral surface of the through-hole 24 for loosely inserting therein the grounding contact 19 is not applied with the insulative coating 34. Instead, the metal is allowed to expose outside at the inner peripheral surface of the through hole 24 so that the grounding contact 19 can contact the conductive metal surface, thereby enhancing the grounding effect.

The metal-made porous plate 13 is connected to the grounding line at its proper place. By doing so, signal can be sent at a high speed and thus, a high speed inspection can be realized.

A pin-type power contact 33 is loosely inserted into the through-hole 31, whose inner peripheral surface is applied with the insulative coating 34, of the resistor array board. The power contact 33 is a contactor having a compression elasticity in the thickness direction of the board 11. The common power main line of the common wiring board 3 and the power line of the inspection circuit board 4 are connected to each other, so that electric power can be supplied to each IC chips 7 array.

FIG. 1 shows a common address main line 8a and an input/output main line 8b as the common signal main line formed by the common wiring board 3. As shown in FIG. 4, the branch line 9 is branch wired to each IC chip 7 belonging to the group G′ in the vertical (or horizontal) row among the groups G1 to Gn from the common address signal main line 8a, and on the other hand, the branch line 9 is branch wired to each IC ship 7 belonging to the group G “in the horizontal (or vertical) row in the group” among the groups G1 to Gn from the common input/output signal main line 8b, and then the protective resistor R is inserted in each branch line 9.

An address signal from the tester main body 1 flows to the common address signal main line 8a, and the signal is supplied to each IC chip in the group G′ through the branch line 9 so that an address is opened.

On the other hand, an input/output signal from the tester main body 1 flows to the common input/output signal main line 8b, and the signal is supplied to each IC chip 7 in the group G″ through the branch line 9 so that an inspection signal is input into the opened address. Then, a response signal to this inspection signal is input into the tester main body 1 through the same branch line 9 and the common input/output signal main line 8b, so that inspection can be conducted.

Although one embodiment has been described hereinbefore in which the inspection of an IC memory is an object to be inspected, the signal line can also be commonly used in other kinds of IC through the protective resistor R.

According to the present invention, by commonly using the signal main line for each group, the number of the common signal main lines can be extensively reduced to the number obtained by dividing the number of the branch lines by the number of the groups.

Moreover, the purpose of insertion of the protective resistor in each group is easily achieved by a provision of only one resistor array board. Owing to insertion of the protective resistor, even if a short-circuit breakage should occur to a certain IC chip in a group, short of supply of electric power, which would otherwise occur to those IC chips in other groups, could effectively be prevented by the protective resistor. Thus, inspection for each divided group and the reduction of the number of lines can be realized in an appropriate manner. This makes it possible to encourage the industrialization of burn-in test, etc. at a wafer level.

Moreover, the assembly of the inspection circuit board, the common wiring board and the resistor array board can be constituted easily and efficiently, and the large number of protective resistors array can be divided into groups and orderly arranged. In addition, maintenance and replacement can be made easily in the case where the protective resistor is broken.

Moreover, the resistor array board is interposed between the inspection circuit board and the common wiring board such that surfaces of those boards are in opposing relation to each other. At each surface of the resistor array board, the protective resistors are contacted with the inspection circuit board and the common wiring board, respectively. By doing so, the purpose of insertion of the protective resistor and the thinner design of the entire apparatus can be achieved simultaneously.

In addition to the above-mentioned constitution, by interposing the resistor array board between the inspection circuit board and the common wiring board thereby to form an assembly of the three component parts, the protective resistor can be press-sandwiched between the two boards so that an electrical contact of the protective resistor is achieved under an appropriate pressure.

Moreover, the grounding line can easily be formed between the common wiring board and the inspection circuit board through the grounding contact of the resistor array board.

Moreover, the power source line can easily be formed between the common wiring board and the inspection circuit board through the power contact of the resistor array board.

What is claimed is:

1. An apparatus for inspecting an IC wafer in which an IC chips array on the IC wafer is divided into plural groups and inspection is carried out for each group, said apparatus comprising an inspection circuit board for sending and receiving a signal to and from said IC chips array on said IC wafer, a common wiring board having a signal main line common to the respective IC chips array of each group and for connecting said tester main body to said inspection circuit board, and a resistor array board having a plurality of protective resistors, said inspection circuit board, said common wiring board and said resistor array board being arranged between said inspection circuit board and said common wiring board such that surfaces of said boards are in opposing relation to each other, one end of each protective resistor being connected to said inspection circuit board at one surface of said resistor array board and the other end being connected to said common wiring board at the other surface of said resistor array board.

2. An apparatus for inspecting an IC wafer according to claim 1, wherein said inspecting circuit board, said resistor array board and said common wiring board are formed into an integral assembly and said resistor array board, and said resistor array board is press-sandwiched between said inspection circuit board and said common wiring board.

3. An apparatus for inspecting an IC wafer according to claim 1 or 2, wherein said resistor array board has a grounding contact, and a grounding line is formed between said common wiring board and said inspection circuit board through said grounding contact.

4. An apparatus for inspecting an IC wafer according to claim 1, 2 or 3, wherein said resistor array board has a power source contact, and a power source line is formed between said common wiring board and said inspection circuit board through said power source contact.
